(19) United States
(12) Patent Application Publication
(10) Pub. No.: US 2026/0314038 A1
(43) Pub. Date: Oct. 8, 2026

(54) SEMICONDUCTOR DEVICE HAVING INTEGRATED PLANAR MOSFETS AND AN INTEGRATED TRENCH SCHOTTKY BARRIER DIODE

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/446,449

(22) Filed: Jan. 12, 2026

Related U.S. Application Data
(60) Provisional application No. 63/747,269, filed on Jan. 20, 2025.

(51) Int. Cl. H10D 84/00; H10D 84/01

(52) U.S. Cl. CPC H10D 84/146; H10D 84/0109

(57) ABSTRACT

A semiconductor device comprising a volume of semiconductor material including a first end, a second end spaced vertically from the first end, a first side, and a second side spaced laterally from the first side; a first integrated planar MOSFET located at the first side of the volume of semiconductor material; a second integrated planar MOSFET located at the second side of the volume of semiconductor material; and a trench located at the first end of the volume of semiconductor material between the first and second integrated planar MOSFETs. An integrated trench Schottky barrier diode comprising a Schottky metal is located within the trench. Methods for making the semiconductor device are also disclosed.

### RELATED APPLICATION

The present U.S. non-provisional patent application is related to and claims priority benefit of an earlier-filed U.S. provisional patent application Ser. No. 63/747,269 filed Jan. 20, 2025. The entire content of the identified earlier-filed application is incorporated by reference as if fully set forth herein.

### TECHNICAL FIELD

The present disclosure relates to power semiconductor devices and methods of making them. More particularly, various examples of the present disclosure relate to a semiconductor device including one or more integrated planar metal oxide semiconductor field-effect transistors (MOSFETs) and one or more integrated trench Schottky barrier diodes (SBDs).

### BACKGROUND

A MOSFET is an active, voltage-controlled semiconductor device, in which varying an electrical voltage between a gate and a body controls an electrical current flowing through a semiconductor channel between a drain and a source. Applications for MOSFETs include, but are not limited to, audio and video (A/V) equipment/technology such as cameras, digital media, and display technology; power electronics such as power supplies, power converters, and motor controllers; digital circuitry such as inverters, switchers, and amplifiers; microprocessors and microcontrollers; transportation, including an ever and rapidly increasing number of electric vehicles; and radio-frequency (RF) applications including oscillators, mixers, and power amplifiers. It is generally desirable to improve the performance and reduce the cost of MOSFETs, but it can be difficult to do so.

This background discussion is intended to provide related information, and is not necessarily prior art.

### SUMMARY

Broadly, examples may concern one or more SBDs and one or more planar MOSFETs physically and functionally integrated into a semiconductor device and methods for making such a device. The SBD may be adjacent to the MOSFET. In examples in which the semiconductor device includes multiple integrated planar MOSFETs, an SBD may be positioned between each of the MOSFETs. Examples advantageously provide the benefit(s) of reduced cell pitch, allowing for the manufacture of more MOSFETs and an SBD on the same die, thereby reducing manufacturing costs.

In an example, a semiconductor device may include a volume of semiconductor material. The volume of semiconductor material may include a first end, a second end spaced vertically from the first end, a first side, and a second side spaced laterally from the first side. The semiconductor device may also include an integrated planar MOSFET located at the first end and at or near the first side of the volume of semiconductor material. A trench may extend into the volume of semiconductor material from the first end thereof. The semiconductor device may further include an integrated trench SBD located at the first end of the volume of semiconductor material and adjacent to the first integrated planar MOSFET. The integrated trench SBD may include a Schottky metal at least partially filling the trench.

The preceding example may further include any one or more of the following features.

The integrated planar MOSFET may further include a first transistor side, a second transistor side spaced laterally apart from the first transistor side, and a gate.

The transistor side may include a first well located at the first end of the volume of semiconductor material.

The second transistor side may include a second well located at the first end of the volume of semiconductor material spaced laterally from the first well.

The gate may be located at the first end of the volume of semiconductor material, may be above each of the first and second transistor sides, and may overlap at least a portion of each of the first and second wells.

The first transistor side may further include a first source, a first body, and a drain. The first source may include a first N+ material located above and adjacent to the first well. The first body may include a first P+ material located adjacent to the first source. The drain may include an N+ substrate material located at the second end of the volume of semiconductor material. The first well may be formed of a P-type material.

The second transistor side may further include a second source, a second body, and a drain. The second source may include a first N+ material located above and adjacent to the second well. The second body may include a first P+ material located adjacent to the second source. The drain may include an N+ substrate material located at the second end of the volume of semiconductor material. The second well may be formed of a P-type material.

A first channel may extend through the volume of semiconductor material between the first source and the drain, and a second channel may extend through the volume of semiconductor material between the second source and the drain.

The Schottky metal may be selected from the group consisting of: titanium, aluminum, molybdenum, platinum, chromium, tungsten, and combinations thereof.

The first and second transistor sides may be part of a common “transistor unit cell,” and the integrated trench SBD may be located outside of the transistor unit cell.

In another example, a semiconductor device may include a volume of semiconductor material. The volume of semiconductor material may include a first end, a second end spaced vertically from the first end, a first side, and a second side spaced laterally from the first side. The semiconductor device may also include a first integrated planar MOSFET located at the first side of the volume of semiconductor material and a second integrated planar MOSFET located at the second side of the volume of semiconductor material. A trench may extend into the volume of semiconductor material from the first end thereof. The trench may be positioned between the first and second integrated planar MOSFETs. An integrated trench SBD may be located at the first end of the volume of semiconductor material and between the first and second integrated planar MOSFETs. The integrated trench SBD may include a Schottky metal at least partially filling the trench.

The preceding example may further include any one or more of the following features.

The first integrated planar MOSFET may further include a first transistor side, a second transistor side spaced laterally apart from the first transistor side, and a gate.

The first transistor side included in the first integrated planar MOSFET may include a first well located at the first end of the volume of semiconductor material.

The second transistor side included in the first integrated planar MOSFET may include a second well located at the first end of the volume of semiconductor material spaced laterally from the first well.

The first transistor side of the first integrated planar MOSFET may further include a first source, a first body, and a drain. The first source may include a first N+ material located above and adjacent to the first well. The first body may include a first P+ material located adjacent to the first source. The drain may include an N+ substrate material located at the second end of the volume of semiconductor material. The first well may be formed of a P-type material.

The second transistor side of the first integrated planar MOSFET may further include a second source, a second body, and a drain. The second source may include a first N+ material located above and adjacent to the second well. The second body may include a first P+ material located adjacent to the second source. The drain may include an N+ substrate material located at the second end of the volume of semiconductor material. The second well may be formed of a P-type material.

The gate included in the first integrated planar MOSFET may be located at the first end of the volume of semiconductor material, may be positioned above each of the first and second transistor sides of the first integrated planar MOSFET, and may overlap at least a portion of each of the first and second wells of the first integrated planar MOSFET.

The second integrated planar MOSFET included in the disclosed semiconductor device may also further include a first transistor side, a second transistor side spaced laterally apart from the first transistor side, and a gate.

The first transistor side included in the second integrated planar MOSFET may include a first well located at the first end of the volume of semiconductor material.

The second transistor side included in the second integrated planar MOSFET may include a second well located at the first end of the volume of semiconductor material spaced laterally from the first well.

The first transistor side of the second integrated planar MOSFET may further include a first source, a first body, and a drain. The first source may include a first N+ material located above and adjacent to the first well. The first body may include a first P+ material located adjacent to the first source. The drain may include an N+ substrate material located at the second end of the volume of semiconductor material. The first well may be formed of a P-type material.

The second transistor side may further include a second source, a second body, and a drain. The second source may include a first N+ material located above and adjacent to the second well. The second body may include a first P+ material located adjacent to the second source. The drain may include an N+ substrate material located at the second end of the volume of semiconductor material. The second well may be formed of a P-type material.

Similar to above, the gate included in the second integrated planar MOSFET may be located at the first end of the volume of semiconductor material, may be positioned above each of the first and second transistor sides of the second integrated planar MOSFET, and may overlap at least a portion of each of the first and second wells of the second integrated planar MOSFET.

A first channel may extend through the volume of semiconductor material between the first source and the drain of the first integrated planar MOSFET. A second channel may extend through the volume of semiconductor material between the second source and the drain of the first integrated planar MOSFET. A third channel may extend through the volume of semiconductor material between the first source and the drain of the second integrated planar MOSFET. A fourth channel may extend through the volume of semiconductor material between the second source and the drain of the second integrated planar MOSFET.

The Schottky metal may be selected from the group consisting of: titanium, aluminum, molybdenum, platinum, chromium, tungsten, and a combination thereof.

This summary is not intended to identify essential features of examples, and is not intended to be used to limit the scope of the claims. These and other aspects of the present examples are described below in greater detail.

### BRIEF DESCRIPTION OF THE DRAWINGS

Examples are described in detail below with reference to the attached drawing figures, wherein:

FIG. 1 illustrates a semiconductor device including integrated planar MOSFET and an integrated trench SBD;

FIG. 2 illustrates a semiconductor device including two integrated planar MOSFETs separated by an SBD;

FIG. 3 illustrates a method flow for making a semiconductor device including an integrated planar MOSFET and an adjacent SBD, as depicted in FIG. 1, with some of the intermediary steps of the method illustrated in FIG. 3 being further described in FIGS. 4A-4G;

FIG. 4A illustrates the result of forming a volume of semiconductor material on a substrate;

FIG. 4B illustrates the result of forming an integrated planar MOSFET in the volume of semiconductor material of 4A;

FIG. 4C illustrates the result of creating a trench in the volume of semiconductor material of 4A;

FIGS. 4D and 4E cooperatively illustrate the results of operations to form a gate for the integrated planar MOSFET of FIG. 4B;

FIG. 4F shows the result of depositing a Schottky metal in the trench formed in FIG. 4C; and

FIG. 4G shows application of metal contacts to result of FIGS. 4A-4F.

The figures are not intended to limit the examples to the specific details depicted. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

Terms of relative location and direction (e.g., above, below, left, right, upper, lower, vertical, horizontal, lateral, and the like) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Various examples of the present disclosure relate to semiconductor devices including one or more integrated planar MOSFETs and one or more integrated trench SBDs and methods for making the same. More particularly, various examples presented herein seek to physically and functionally integrate two (2) planar MOSFETs and a trench SBD into a single, continuous volume of semiconductor material. As such, it will be appreciated that the examples presented herein are directed to a single semiconductor device including a MOSFET(s) and SBD integrally formed into a unitary chip, using a single process.

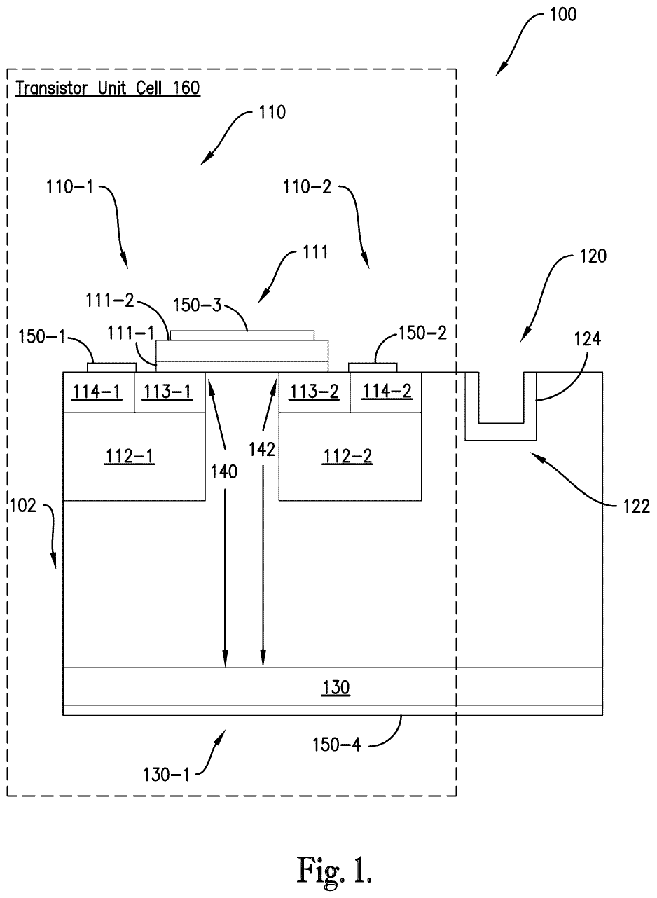

Referring to FIG. 1, an exemplary semiconductor device 100 including a volume of semiconductor material 102 is shown. The semiconductor device 100 may further include an integrated planar MOSFET 110 and an integrated trench SBD 120. The integrated planar MOSFET 110 may include a first transistor side 110-1, a second transistor side 110-2, and a common (and continuous in the illustrated example) gate 111. The volume of semiconductor material 102 may be grown on a substrate material, or substrate, 130. In various examples, the semiconductor device 100 may be a silicon (Si) or a silicon carbide (SiC) device. It will be appreciated that other material compositions of the semiconductor device 100 are within the scope of the present disclosure.

The volume of semiconductor material 102 may include a first end, a second end spaced vertically from the first end, a first side, and a second side spaced laterally from the first side. The volume of semiconductor material 102 may be grown, e.g., epitaxially, on the substrate 130 (located at the second end of the volume of semiconductor material 102). The volume of semiconductor material 102 may be an N-type material and the substrate 130 may be an N+ material. Each of the volume of semiconductor material 102 and the substrate 130 may be grown or otherwise formed from an N-type or N+ material, respectively, or may be doped to be an N-type or N+ material, respectively, after being formed from material(s) having different (e.g., a charge-neutral) compositions.

The first integrated planar MOSFET 110 may be formed, or located, adjacent the first end and at or near the first side of the volume of semiconductor material 102. The first integrated planar MOSFET 110 may include a first transistor side 110-1, a second transistor side 110-2, and a common gate 111.

The first transistor side 110-1 may include a first well 112-1, a first source 113-1, a first body 114-1, and a drain 130-1. The first well 112-1 may be implanted (e.g., via ion implantation) or otherwise provided, and may be or at least partially comprise a P-type material. The first source 113-1 may be implanted or otherwise provided, and may be or at least partially comprise an N+ material. The first body 114-1 may be implanted or otherwise provided, and may be or at least partially comprise a P+ material.

The second transistor side 110-2 may include a second well 112-2, a second source 113-2, a second body 114-1, and the drain 130-1. Each of the second well 112-2, the second source 113-2, and the second body 114-2 may be implanted (e.g., via ion implantation) or otherwise provided. The second well 112-2 may be or at least partially comprise a P-type material. The second source 113-2 may be or at least partially comprise an N+ material. The second body may be or at least partially comprise a P+ material.

A portion of the substrate 130 may serve as the drain 130-1 for each of the first and second transistor sides 110-1, 110-2 of the integrated planar transistor 110.

Generally, the first and second transistor sides 110-1 and 110-2 of the MOSFET 110 may be mirror-images, or “flipped” versions (e.g., flipped horizontally about a point and/or vertical axis of symmetry located therebetween) of each other. In other words, some or all of the respective structures and associated materials may be reversed in order or position on opposite sides of the point/axis of symmetry. The first and second transistor sides 110-1 and 110-2 of the integrated planar MOSFET 110 may otherwise be substantially similar or identical. However, according to some aspects of the example semiconductor devices referenced throughout this disclosure, asymmetries between the first and second transistor sides of the example MOSFET may be permissible. Examples of such asymmetries may include, but are not limited to, structural variations and/or variations in material composition between the corresponding respective structures.

The integrated trench SBD 120 may be formed, or located, adjacent the first end of the volume of semiconductor material 102 at or near the second side thereof. The integrated trench SBD 120 may be formed or otherwise provided in a trench 122. The trench 122 may be formed by etching the first end of the volume of semiconductor material 102 to a desired lateral width and vertical depth. A Schottky metal 124 may be deposited, grown (e.g., epitaxially) or otherwise provided to at least partially fill the trench 122 to form the integrated trench SBD 120. In the illustrated example, the Schottky metal 124 lines (but does not fill) the sides and bottom of the trench 122. Examples of Schottky metals that may be used to form the SBD 120 include, but are not limited to, titanium, aluminum, molybdenum, platinum, chromium, tungsten, and combinations thereof.

In various examples, the first and second sources 113-1, 113-2 may comprise one (1) single-ended source. In other examples, the first and second sources 113-2, 113-2 may each be a standalone source, and the semiconductor device 100 may be a multi-source device.

The gate 111 may be located at the first end of the volume of semiconductor material 102. The gate 111 may also be above each of the first and second transistor sides 110-1, 110-2 and overlap at least a portion of each of the first and second wells 112-1, 112-2. The gate 111 may further include a dielectric layer 111-1 and a polysilicon layer 111-2. The dielectric layer 111-1 may comprise, for example, silicon dioxide (SiO2) or any other suitable gate oxide material. The polysilicon material included in the polysilicon layer 111-2 may be of neutral charge. However, due to manufacturing and material imperfections, the polysilicon material included in the polysilicon layer 111-2 of the gate 111 may be or at least partially comprise a P-type material, or may be doped to be a P-type material. Each of the dielectric layer 111-1 and the polysilicon layer 111-2 may be epitaxially grown or otherwise provided.

As previously mentioned, the substrate 130 may be doped to be an N+ material. The volume of semiconductor material 102 may be fully grown on the substrate 130 prior to any of the above-described steps for implanting, etching, growing, or otherwise providing the various sub-components included in the semiconductor device 100 being performed. At least a portion of the substrate 130 may act as the drain (e.g., the drain 130-1) for the integrated planar MOSFET 110 included in the semiconductor device 100. According to the present disclosure, the integrated planar MOSFET 110, the integrated trench SBD 120, and the substrate 130 (the drain 130-1) are monolithically integrated into one continuous/contiguous structure or chip.

A first channel 140 may extend through the volume of semiconductor material 102 from the first source 113-1 to the drain 130-1. A second channel 142 may extend through the volume of semiconductor material 102 from the second source 113-2 to the drain 130-1. Those of ordinary sill in the art will appreciate that the drain for each of the first and second transistor sides may be formed of the common substrate 130 so as to be contiguous/continuous.

The semiconductor device 100 may further include electrical terminals 150-1 through 150-4 to facilitate application of appropriate electrical signals (e.g., voltages), as discussed below. More specifically, first and second electrical terminals 150-1, 150-2, may be added to the respective first or second sources 113-1, 113-2. The terminals 150-1, 150-2 may be shorted (electrically connected) so that the first and second sources 113-1, 113-2 effectively form a common source. A third electrical terminal 150-3 may be added to the gate 111. A fourth, continuous, electrical terminal 150-4 may be added to the substrate 130, thereby serving as the electrical terminal for the drain 130-1.

In operation, when a voltage, V_{gs}, is applied between the source (e.g., the single-ended source comprising the sources 113-1, 113-2 of FIG. 1) and the gate (e.g., the gate 130-1 of FIG. 1), the generated electric field creates an inversion layer at the semiconductor-dielectric interface. The inversion layer provides the channels 140, 142 through which electrical current can flow when another voltage, V_{ds}, is applied between the source and the drain. More specifically, V_{gs} controls the width of the depletion region at the P-N junction where the charge carriers of the P- and N-type materials comprising the semiconductor device (e.g., the semiconductor device 100) diffuse into each other, which “depletes” the available concentration of majority charge carriers in each material, and thereby controls a current, I_{d}, flowing from the drain to the source.

The first and second transistor sides 110-1, 110-2 may be integrally part of what is traditionally referred to as a “transistor unit cell” 160. The transistor unit cell 160 may not include the integrated trench SBD 120.

Although the first and second transistor sides 110-1, 110-2 may appear identical in FIG. 1 and may have been described as such in the accompanying description, it is to be appreciated that various asymmetries between the first and second transistor sides 110-1, 110-2 may exist. For instance, material compositions and/or physical dimensions of the various sub-components included in each of the first and second transistor sides 110-1, 110-2 may vary, e.g., as dictated by device specification. For instance, the first well 112-1 may be made of a first P-type material while the second well 112-2 may be made of a second P-type material. Additionally and/or alternatively, the first source 113-1 may have a greater lateral width and/or a greater vertical depth than the second source 113-2. Various additional or alternative asymmetries may be permissible under the present disclosure.

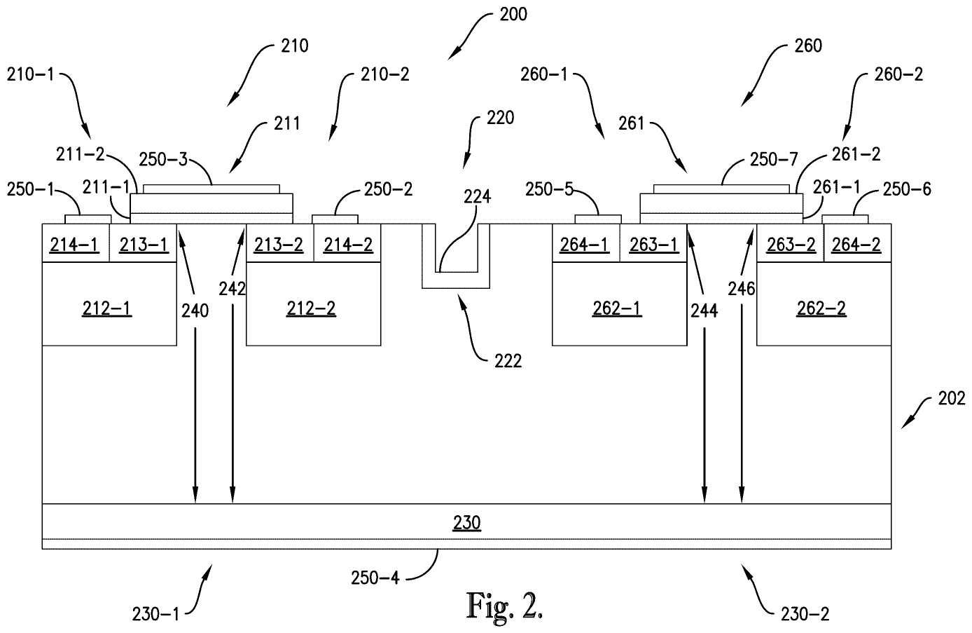

Turning to FIG. 2, a second example semiconductor device 200 formed from a single, continuous volume of semiconductor material 202 is shown. The second semiconductor device 200 may further include a first integrated planar MOSFET 210, an integrated trench SBD 220, and a second integrated planar MOSFET 260. The volume of semiconductor material 202 may be grown, e.g., epitaxially, on a substrate 230, the substrate 230 being located at the second end of the volume of semiconductor material 202. The second semiconductor device 200 may also be a silicon (Si) or a silicon carbide (SiC) device. As before, it will be appreciated that other material compositions of the semiconductor device 200 are within the scope of the present disclosure.

The volume of semiconductor material 202 may include a first end, a second end spaced vertically from the first end, a first side, and a second side spaced laterally from the first side. The volume of semiconductor material 202 may be grown, e.g., epitaxially, on the substrate 230. The volume of semiconductor material 202 may be an N-type material and the substrate 230 may be an N+ material. Each of the volume of semiconductor material 202 and the substrate 230 may be include an N-type or N+ material, respectively, or they may be doped to be an N-type or N+ material, respectively, after being formed from material(s) having different (e.g., a charge neutral) compositions.

The first integrated planar MOSFET 210 included in the semiconductor device 200 may be formed, or located, adjacent the first end and at or near the first side of the volume of semiconductor material 202. The first integrated planar MOSFET 210 may further include a first and second transistor side 210-1, 210-2. Each of the first and second transistor sides 210-1, 210-2 may each include: a respective first and second well 212-1, 212-2; a respective first and second source 213-1, 213-2; and a respective first and second body 214-1, 214-2. A portion of the substrate 230 may serve as a drain 230-1 for the first integrated planar MOSFET 210. A gate 211 including a dielectric layer 211-1 and a polysilicon layer 211-1 may be located at the first end of the volume of semiconductor material 202, above each of the first and second transistor sides 210-1, 210-1, and overlap at least a portion of each of the first and second wells 212-1, 212-2.

The first integrated planar MOSFET 210 of the semiconductor device 200 may be substantially similar or identical (both in form and function) to the integrated planar MOSFET 110 included in the semiconductor device 100 of FIG. 1. That is to say, the material composition, location/placement, physical dimension, function, etc. of each of the various sub-components included in the first integrated planar MOSFET 210 of the semiconductor device 200 may be equivalent to that of the corresponding sub-component of the integrated planar MOSFET 110 of the semiconductor device 100. For instance, each of the first and second sources 213-1, 213-2 of the first integrated planar MOSFET 210 may also be located above and adjacent to the respective first or second well 212-1, 212-2 included therein, be formed from or at least partially comprise an N+ material, and come together (e.g., be electrically coupled) to form one (1) single-ended source. The wells 212-1, 212-2 of the first integrated planar MOSFET 210 are similarly analogous to the wells 112-1, 112-2 of the integrated planar MOSFET 110. The bodies 214-1, 214-2 of the first integrated planar MOSFET 210 are similarly analogous to the bodies 114-1, 114-2 of the integrated planar MOSFET 110. The channels 240, 242; the drain 230-1; the gate 211 (and the dielectric layer 211-1 and the polysilicon layer 211-1 comprising the gate 211); and electrical terminals 250-1 through 250-4 included in first integrated planar MOSFET 210 are all similarly equivalent to their respective analog in the integrated planar MOSFET 110 of FIG. 1.

However, similar to the MOSFET 110 of FIG. 1, asymmetries between the sub-components of the first integrated planar MOSFET 210 are permissible according to certain aspects of the present disclosure.

The integrated trench SBD 220 may be formed in a way that is substantially similar or identical to how the integrated trench SBD 120 of FIG. 1 is formed, and the integrated trench SBD 220 may be materially and functionally equivalent or identical to the integrated trench SBD 120. The integrated trench SBD 220 is positioned between the first and second integrated planar transistors 210, 260.

The second integrated planar MOSFET 260 included in the semiconductor device 200 may be similarly dimensioned and configured (and formed in a similar manner) to the first integrated planar MOSFET 210. In other words, the second integrated planar MOSFET 260 may include sub-components that are substantially equivalent or identical (both in form and function) to the sub-components of the first integrated planar MOSFET 210. Yet further, it may be said that the material composition, location/placement, physical dimension, function, etc. of each of the various sub-components included in the respective first and second integrated planar MOSFETs 210 and 260 may be equivalent. With particular respect to the second integrated MOSFET, first and second sources 263-1, 263-2 maybe located above and adjacent to respective first and second wells 262-1, 262-2, be formed from or at least partially comprise an N+ material, and come together (e.g., be electrically connected) to form one (1) single-ended source. The wells 262-1, 262-2 of the second integrated planar MOSFET 260 are similar to the wells 212-1, 212-2 of the first integrated planar MOSFET 210. The bodies 264-1, 264-2 of the second integrated planar MOSFET 260 are similar to the bodies 214-1, 214-2 of the first integrated planar MOSFET 210. The channels 244, 246; the drain 230-1; the gate 261 (and the dielectric layer 261-1 and the polysilicon layer 261-1 comprising the gate 261); and electrical terminals 250-4 through 250-7 included in the second integrated planar MOSFET 260 are all similar to their respective analogs in the first integrated planar MOSFET 210.

As above, various asymmetries between the sub-components of the second integrated planar MOSFET 260 are within the ambit of certain aspects of the present disclosure. Asymmetries between the first and second integrated planar MOSFETs 210, 260 are also permissible under some aspects of the present disclosure.

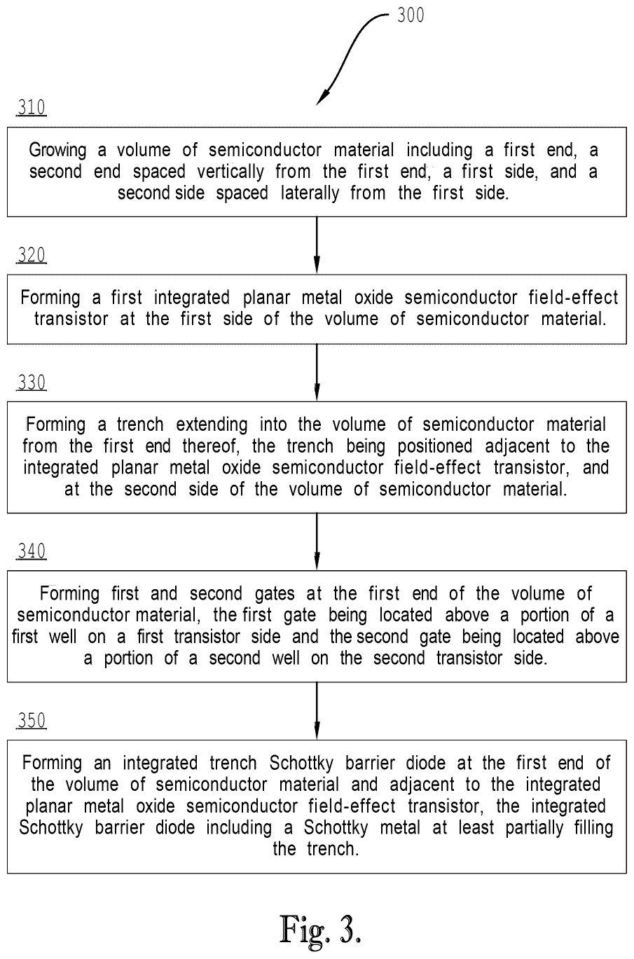

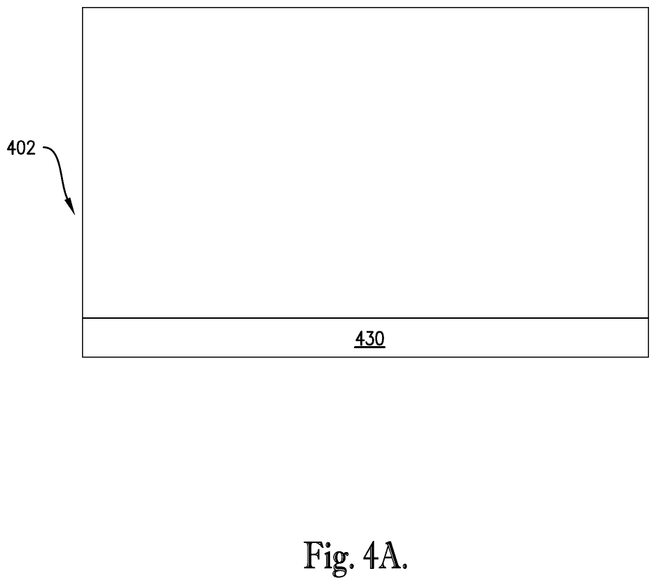

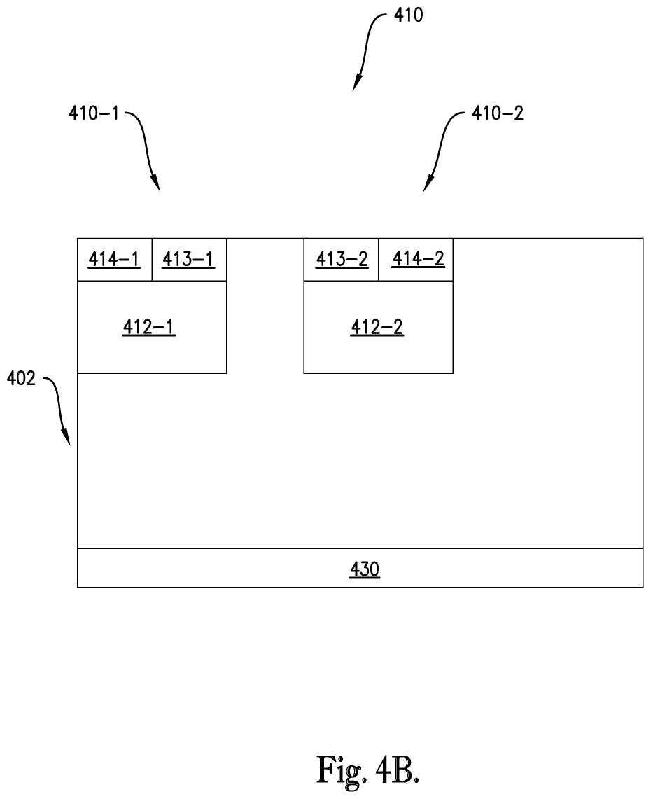

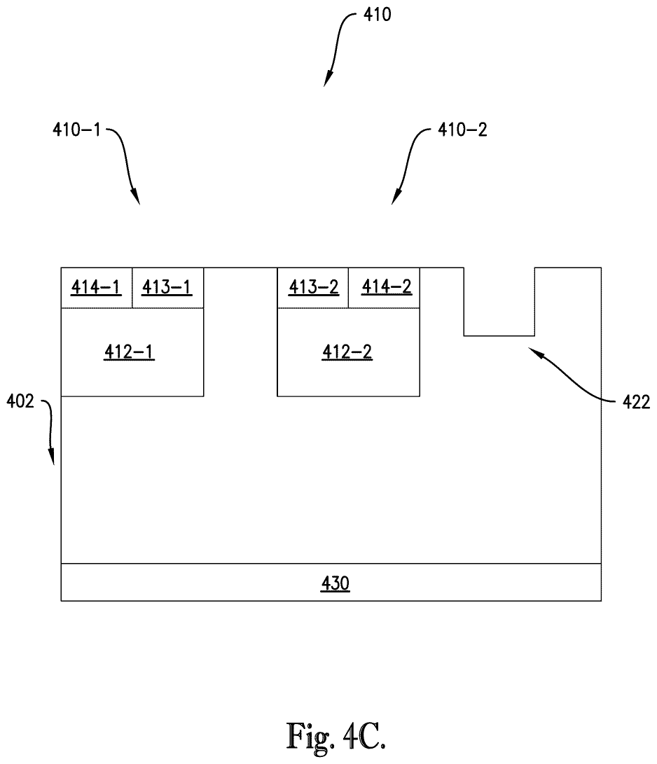

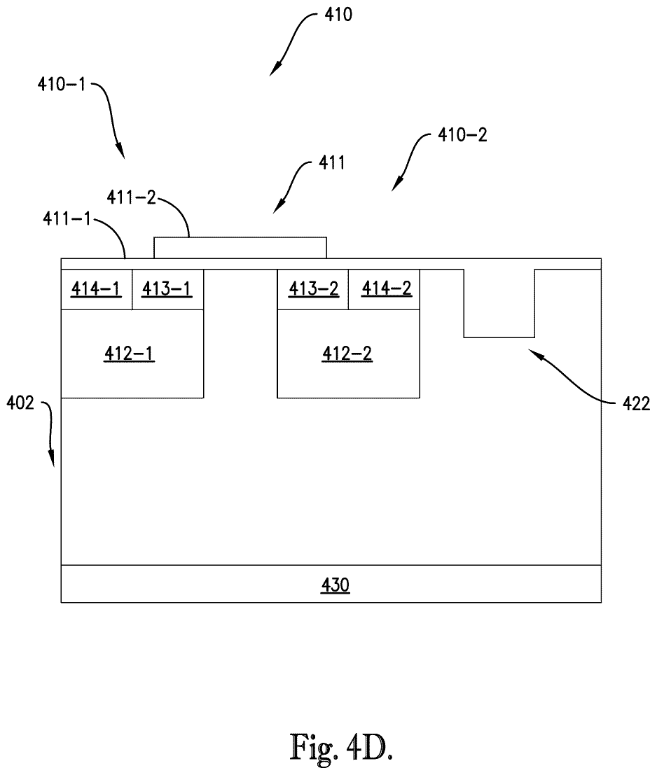

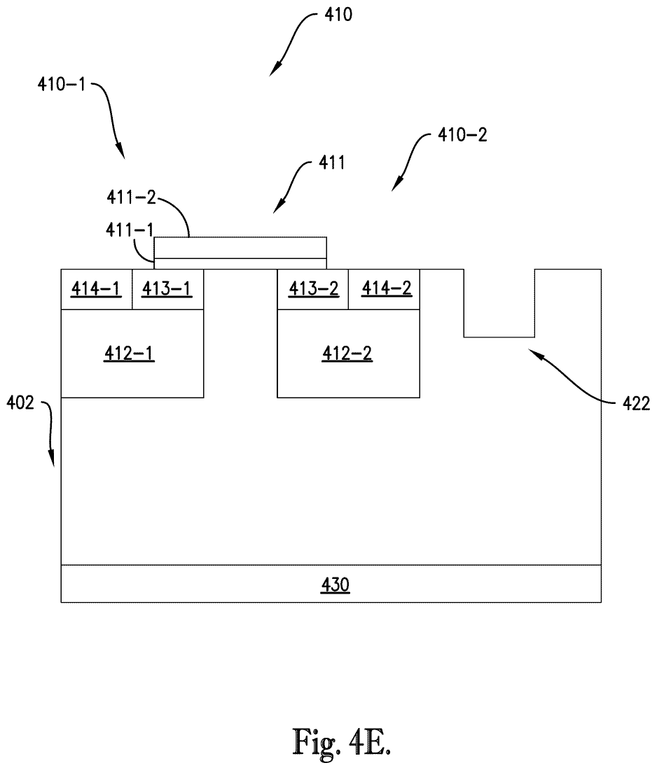

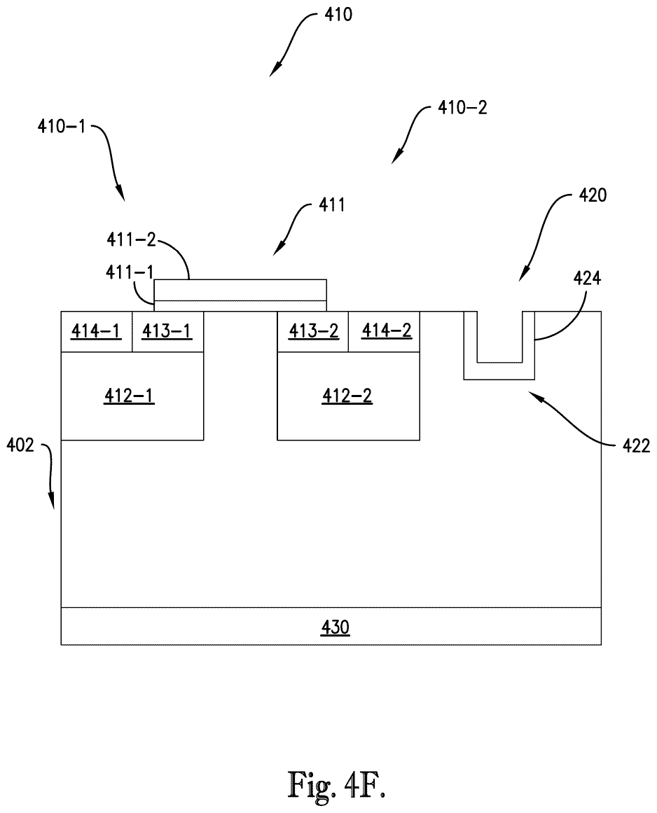

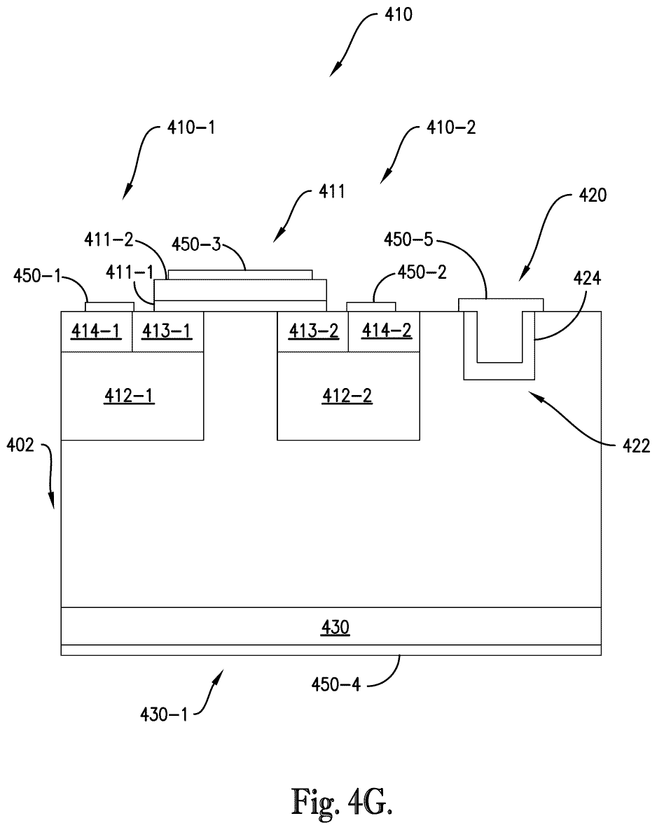

Referring to FIG. 3, an example of a method 300 of making a semiconductor device including an integrated planar MOSFET and an adjacent integrated trench SBD may include the following operations. References are also made to FIGS. 4A-4G showing the results of certain of the operations of the method 300 and to FIG. 1 and the example semiconductor device 100 described above which may be made using the method 300. As discussed above, the first and second transistor sides included in the integrated planar MOSFET may be mirror-images, or “flipped” versions of each other. As such, the first and second transistor sides of the integrated planar MOSFET included in the example semiconductor device may be substantially similar or identical to one another, although some asymmetries between transistor sides may be contemplated under the present disclosure. Further, the first and second transistor sides form a “transistor unit cell.” An integrated trench SBD may be located adjacent to the integrated planar MOSFET. However, the integrated trench SBD is not included in the “transistor unit cell” but is part of the same chip.

It will be appreciated that multiple integrated planar MOSFETs may be included in the example semiconductor device. In those examples, the integrated trench SBD may be located between each pair of integrated planar MOSFETs. It will be further appreciated that the example semiconductor device may include multiple instances of the “transistor unit cell.”

Unless expressly stated otherwise or as will be understood by one of ordinary skill in the art, operations of the method 300 may be performed sequentially or concurrently, and some operations of the method 300 may be optional.

At operation 310, a volume of semiconductor material (e.g., the volume of semiconductor material 402 of FIG. 4A) may be formed. The volume of semiconductor material may include a first end, a second end spaced vertically from the first end, a first side, and a second side spaced laterally from the first side. The volume of semiconductor may be epitaxially grown, or otherwise provided, on a substrate, e.g., the substrate 430 of FIG. 4A. The volume of semiconductor material 402 may be an N-type material and the substrate 430 may be an N+ material. Each of the volume of semiconductor material 402 and the substrate 430 may be a continuous volume/structure of material.

At operation 320, an integrated planar transistor, such as the integrated planar transistor 410 of FIG. 4B, is formed. Forming the integrated planar transistor 410 may further include forming a first transistor side and second a transistor side (e.g., the first and second transistor sides 410-1, 410-2 of FIG. 4B). The first and second transistor sides 410-1, 410-2 may be positioned at the first end and at or near the respective first or second side of the volume of semiconductor material 402. Each of the first and second transistor sides 410-1, 410-2 may include a respective first or second well (e.g., the wells 412-1, 412-2), a respective first or second source (e.g., the sources 413-1, 413-2), and a respective first or second body (e.g., the bodies 414-1, 414-2). The first and second transistor sides 410-1, 410-2 may be formed simultaneously. Each of the wells 412-1, 412-2, the sources 413-1, 413-2, and each of the bodies 414-1, 414-2 may be implanted, or otherwise provided. Each of the wells 412-1, 412-2 may be formed of or include a P-type material. Each of the sources 413-1, 413-2 may be formed of or include an N+ material. Each of the bodies 414-1, 414-2 may be formed of or include a P+ material.

The first and second sources 413-1, 413-2 may be combined (electrically coupled) via a single-ended source terminal.

At operation 330, a trench, e.g., the trench 422 of FIG. 4C, extending into the volume of semiconductor material 402 from the first end thereof is formed. The trench 422 may be formed via etching. The trench 422 may be a shallow trench.

At operation 340, a gate, such as the gate 411 of FIG. 4D is formed. Forming the gate 411 may include growing, depositing, or otherwise providing a dielectric material, such as a continuous, thin layer of dielectric material 411-1 over the entire top surface of the volume of semiconductor material 402. In various examples, the trench 422 may be filled with dielectric material 411-1 before the dielectric material 411-1 is provided over the top surface of the volume of semiconductor material 402. A polysilicon layer 411-2 made of or including a polysilicon material may be formed over a portion of the layer of dielectric material 411-1. The dielectric material 411-1 may be or include silicon dioxide (SiO₂) or any other suitable dielectric or gate oxide material. The polysilicon material included in the polysilicon layer 411-2 may be charge neutral. However, due to material and/or manufacturing defects, in various examples, the polysilicon material may be a P-type material. Alternatively, the polysilicon material may be doped to be charge neutral.

Turning to FIG. 4E, forming the gate 411 may further include etching away the layer of dielectric material 411-1 except for the portion that is directly underneath the layer of polysilicon material 411-2. This operation may include etching away all dielectric material filling the trench 422. After etching, the remaining portion of the layer of dielectric material 411-1 and the layer of polysilicon material 411-2 collectively form the gate 411. As illustrated in FIG. 4D 4G, the gate 411 formed during operation 340 is located at the first end of the volume of semiconductor material 402. The gate 411 is also located over each of the first and second transistor sides 410-1, 410-2 and overlaps at least a portion of the first and second wells 412-1, 412-2.

At operation 350, an integrated trench SBD (e.g., the integrated trench SBD 420 of FIG. 4F) may be formed. The integrated trench SBD 420 may be formed at the first end of the volume of semiconductor material 402. The integrated trench SBD 420 may be located adjacent to the integrated planar transistor 410. The integrated trench SBD 420 may comprise a Schottky metal 424 that at least partially fills the trench 422. The Schottky metal, which may be selected from the group consisting of: titanium, aluminum, molybdenum, platinum, chromium, tungsten, and a combination thereof, may be deposited, grown, or otherwise provided into the trench 422.

It will be appreciated that metal contacts (e.g., the metal contacts 450-1 through 450-4 of FIG. 4G) may be deposited or otherwise provided on each of the first and second sources 413-1, 413-2, the gate 411, the substrate 430, and the Schottky metal 424. Providing the metal contact on the substrate 430 may turn at least a portion of the substrate 430 into a drain (e.g., the drain 430-1 of FIG. 4G). Further, providing the metal contacts 450-1 through 450-5 may facilitate application and/or transmission of electrical signals to/from the integrated planar MOSFET 410 and/or the integrated trench SBD 420.

Further, a second integrated planar MOSFET (e.g., the second integrated planar MOSFET 260 of FIG. 2) may be formed in the volume of semiconductor material at the second side thereof, so that the SBD 420 is positioned between the first integrated planar MOSFET 410 and the second integrated planar MOSFET.

Additional details related to the operations of the method 300 or the results of certain operations of the method 300 depicted in FIGS. 4A-4G may be found in FIGS. 1 and 2, and the corresponding descriptions.

Additional processing may be performed as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

Although described herein with regard or in relation to one or more particular kinds of electronic devices (e.g., junction field-effect transistor, metal oxide semiconductor field-effect transistor), the technology may be more broadly applicable to one or more other kinds of electronic devices as well.

One with ordinary skill in the art will recognize that the technology described herein may, when applicable, be implemented in enhancement mode or depletion mode.

Further, the technology described herein may, when applicable, be implemented as an N-channel or P-channel device, wherein, in general, regions that are N-doped or P-doped in N-channel implementations may be, respectively, P-doped or N-doped in P-channel implementations.

Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide (Al₂O₃), hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17.

Relatedly, a structure or region may contain two or more different doping doses. For example, one with ordinary skill in the art will recognize that some P-wells may contain a lower dose P-well portion and a higher dose unclamped inductive switching portion.

What is claimed is:

1. A semiconductor device comprising:
a volume of semiconductor material including a first end, a second end spaced vertically from the first end, a first side, and a second side spaced laterally from the first side;
an integrated planar metal oxide semiconductor field-effect transistor located at the first side of the volume of semiconductor material;
a trench extending into the volume of semiconductor material from the first end thereof; and
an integrated trench Schottky barrier diode located at the first end of the volume of semiconductor material and adjacent to the first integrated planar metal oxide semiconductor field-effect transistor, the integrated Schottky barrier diode including a Schottky metal at least partially filling the trench.

2. The semiconductor device of claim 1, the integrated planar metal oxide semiconductor field-effect transistor including—
a first transistor side,
a second transistor side spaced laterally apart from the first transistor side, and
a gate.

3. The semiconductor device of claim 2, wherein:
the first transistor side includes a first well located at the first end of the volume of semiconductor material,
the second transistor side includes a second well located at the first end of the volume of semiconductor material spaced laterally from the first well, and
the gate is located at the first end of the volume of semiconductor material, is above each of the first and second transistor sides, and overlaps at least a portion of each of the first and second wells.

4. The semiconductor device of claim 3, wherein the first transistor side further includes
a first source including a first N+ material located above and adjacent to the first well,
the first well being formed of a P-type material,
a first body including a first P+ material located adjacent to the first source, and
a drain including an N+ substrate material located at the second end of the volume of semiconductor material.

5. The semiconductor device of claim 4, wherein the second transistor side further includes—
a second source including a second N+ material located above and adjacent to the second well,
the second well being formed of a P-type material,
a second body including a second P+ material located adjacent to the second source, and the drain.

6. The semiconductor device of claim 3,
a first channel extending through the volume of semiconductor material between the first source and the drain, and
a second channel extending through the volume of semiconductor material between the second source and the drain.

7. The semiconductor device of claim 1, wherein the Schottky metal is selected from the group consisting of: titanium, aluminum, molybdenum, platinum, chromium, tungsten, and a combination thereof.

8. The semiconductor device as claimed in claim 3,
the first and second transistor sides being part of a common transistor unit cell,
the trench and integrated trench Schottky barrier diode being located outside the transistor unit cell.

9. A semiconductor device comprising:
a volume of semiconductor material including a first end, a second end spaced vertically from the first end, a first side, and a second side spaced laterally from the first side;
a first integrated planar metal oxide semiconductor field-effect transistor located at the first side of the volume of semiconductor material;
a second integrated planar metal oxide semiconductor field-effect transistor located at the second side of the volume of semiconductor material;
a trench extending into the volume of semiconductor material from the first end thereof, the trench being positioned between the first and second integrated planar metal oxide semiconductor field-effect transistors; and
an integrated trench Schottky barrier diode located at the first end of the volume of semiconductor material and between the first and second integrated planar metal oxide semiconductor field-effect transistors, the integrated Schottky barrier diode including a Schottky metal at least partially filling the trench.

10. The semiconductor device of claim 9, the first integrated planar metal oxide semiconductor field-effect transistor further including
a first transistor side,
a second transistor side spaced laterally apart from the first transistor side, and
a gate.

11. The semiconductor device of claim 10, wherein:
the first transistor side includes a first well located at the first end of the volume of semiconductor material,
the second transistor side includes a second well located at the first end of the volume of semiconductor material, and
the gate is located at the first end of the volume of semiconductor material, is above each of the first and second transistor sides, and overlaps at least a portion of each of the first and second wells.

12. The semiconductor device of claim 11, the first transistor side further including—
a first source including a first N+ material located above and adjacent to the first well,
the first well being formed of a P-type material,
a first body including a first P+ material located adjacent to the first source, and
a drain including an N+ substrate material located at the second end of the volume of semiconductor material.

13. The semiconductor device of claim 12, the second transistor side further including
a second source including a second N+ material located above and adjacent to the second well,
the second well being formed of a P-type material,
a second body including a second P+ material located adjacent to the second source, and
the drain.

14. The semiconductor device of claim 9, the second integrated planar metal oxide semiconductor field-effect transistor further including
a first transistor side,
a second transistor side spaced laterally apart from the first transistor side, and
a gate.

15. The semiconductor device of claim 14, wherein:
the first transistor side includes a first well located at the first end of the volume of semiconductor material,
the second transistor side includes a second well located at the first end of the volume of semiconductor material, and
the gate is located at the first end of the volume of semiconductor material, is above each of the first and second transistor sides, and overlaps at least a portion of each of the first and second wells.

16. The semiconductor device of claim 15, the first transistor side further including—
a first source including a first N+ material located above and adjacent to the first well,
the first well being formed of a P-type material,
a first body including a first P+ material located adjacent to the first source, and
a drain including an N+ substrate material located at the second end of the volume of semiconductor material.

17. The semiconductor device of claim 16, the second transistor side further including
a second source including a second N+ material located above and adjacent to the second well,
the second well being formed of a P-type material,
a second body including a second P+ material located adjacent to the second source, and
the drain.

18. The semiconductor device of claim 15,
a first channel extending through the volume of semiconductor material between the first source side and the drain,
a second channel extending through the volume of semiconductor material between the second source side and the drain.

19. The semiconductor device of claim 9, the wherein the Schottky metal is selected from the group consisting of: titanium, aluminum, molybdenum, platinum, chromium, tungsten, and a combination thereof.
